(19) United States
(12) Patent Application Publication
(10) Pub. No.: US 2026/0181911 A1
(43) Pub. Date: Jun. 25, 2026

(54) NEURON DEVICE BASED ON MAGNETIC TUNNEL JUNCTION, AND NEURAL NETWORK APPARATUS

(71) Applicant: Institute of Microelectronics, Chinese Academy of Sciences, Beijing (CN)

(72) Inventors: Guozhong XING, Beijing (CN); Ziwei WANG, Beijing (CN); Xuefeng ZHAO, Beijing (CN); Di Wang, Beijing (CN); Long LIU, Beijing (CN); Huai LIN, Beijing (CN); Hao Zhang, Beijing (CN)

(21) Appl. No.: 18/856,555

(22) PCT Filed: May 11, 2022
(86) PCT No.: PCT/CN2022/092117

§ 371 Date: Oct. 11, 2024

(30) Foreign Application Priority Data
Apr. 12, 2022 (CN) 202210381021.7

(51) Int. Cl. H10B 61/00; G06N 3/065; H10N 50/10

(52) U.S. Cl. CPC H10B 61/20; G06N 3/065; H10N 50/10

(57) ABSTRACT

A neuron device based on magnetic tunnel junction and a neural network apparatus are provided, where the neuron device based on magnetic tunnel junction includes: a synthetic antiferromagnetic layer, where a first side of the synthetic antiferromagnetic layer is provided with a bottom electrode; a barrier layer arranged on a second side of the synthetic antiferromagnetic layer; a ferromagnetic free layer arranged on a side of the barrier layer away from the bottom electrode; a top electrode arranged on a side of the ferromagnetic free layer away from the bottom electrode; a first boundary antiferromagnetic pinning layer and a second boundary antiferromagnetic pinning layer both arranged on the side of the ferromagnetic free layer away from the bottom electrode, and respectively located on two sides of the top electrode.

### CROSS-REFERENCE TO RELATED APPLICATION

The present application claims priority to Chinese Patent Application No. 202210381021.7, titled “neuron device based on magnetic tunnel junction, and neural network apparatus”, filed on Apr. 12, 2022, the contents of which are incorporated herein by reference.

### TECHNICAL FIELD

The present disclosure relates to a field of artificial neural network technology, and in particular, to a neuron device based on magnetic tunnel junction and a neural network apparatus.

### BACKGROUND

With the rapid development of the field of artificial intelligence, the demand for large-scale data processing has sharply increased. Neural networks exhibit unique advantages due to their ability to improve the efficiency of processing complex tasks and reduce power consumption. At present, although various algorithms have greatly developed artificial neural networks, the progress of neuromorphic computing is still limited by the lack of dedicated hardware. Given the gradual slowdown in the development of Moore's Law and the limitation of the von Neumann bottleneck, the computational speed and energy efficiency of CMOS (Complementary Metal Oxide Semiconductor) hardware are gradually approaching their theoretical limits, and the emerging spintronic devices, due to their ultrafast dynamics, low power consumption, non-volatility, high endurance, and randomness, have significant advantages and potential applications in neuromorphic computing. The core of neural networks lie in realizing the functions of neurons and synapses. The use of spintronics devices may effectively simulate synaptic weight function, and multi-configuration modulation may be achieved by regulating and controlling the tunneling magnetoresistance of magnetic tunnel junction (MTJ). The non-volatile resistor may be used to form a cross point array to achieve the key “vector matrix” multiplication function in neural networks. However, due to the relatively complex functions of neurons, there is relatively little research on the hardware implementation of neurons. Neuroscience research shows that the functions of neurons include: accumulating excitation signals from external inputs, releasing output signals to the outside when a certain threshold is reached, and gradually leaking accumulated signals when there is no input excitation, i.e., leaky-integrate-fire (LIF) function. Spintronic devices based on magnetic domain wall motion have great potential in hardware implementation of neuron devices, and the motion of a magnetic domain wall may be driven through Spin-Transfer Torque (STT) or Spin-Orbit Torque (SOT). The auto-reset function of the magnetic domain wall may be achieved through device structure and material settings. The tunneling magnetoresistance of the magnetic tunnel junction changes when the magnetic domain wall moves to the threshold position, and combined with an external circuit, a current spike signal may be output. Therefore, the leaky-integrate-fire function of neurons may be effectively simulated by a fully electronic control method, providing a feasible solution for the hardware implementation of large-scale high-speed parallel computing in neural networks.

At present, in the prior art, a self-leakage function may be realized by using magnetic fields generated by hard magnets, energy gradients generated by trapezoidal ferromagnetic free layers, or energy gradients generated by uniaxial magnetic anisotropy gradients. The magnetic domain wall is driven to move through the spin transfer torque, and when the magnetic domain wall moves to the threshold region, a spike pulse signal is output by causing the change of tunneling magnetoresistance of the magnetic tunnel junction, so as to simulate the leaky-integrate-fire function of neurons. However, in the prior art, it is difficult to control the leakage speed when implementing the leakage function.

### SUMMARY

An object of the present disclosure is at least in part to provide a neuron device based on magnetic tunnel junction and a neural network apparatus.

In a first aspect, the present disclosure provides a neuron device based on magnetic tunnel junction, including: a synthetic antiferromagnetic layer, wherein a first side of the synthetic antiferromagnetic layer is provided with a bottom electrode; a barrier layer arranged on a second side of the synthetic antiferromagnetic layer; a ferromagnetic free layer arranged on a side of the barrier layer away from the bottom electrode, wherein a stray field to which the ferromagnetic free layer is subjected is determined by a structure of the synthetic antiferromagnetic layer; a top electrode arranged on a side of the ferromagnetic free layer away from the bottom electrode; a first boundary antiferromagnetic pinning layer and a second boundary antiferromagnetic pinning layer both arranged on the side of the ferromagnetic free layer away from the bottom electrode, and respectively located on two sides of the top electrode; wherein the first boundary antiferromagnetic pinning layer and the second boundary antiferromagnetic pinning layer are respectively used to determine a magnetization direction at two ends of the ferromagnetic free layer, such that a magnetic domain wall in the ferromagnetic free layer move between the first boundary antiferromagnetic pinning layer and the second boundary antiferromagnetic pinning layer; a first boundary electrode arranged on a side of the first boundary antiferromagnetic pinning layer away from the bottom electrode; and a second boundary electrode arranged on a side of the second boundary antiferromagnetic pinning layer away from the bottom electrode.

In some embodiments, a width of the synthetic antiferromagnetic layer at different length positions is the same, such that the ferromagnetic free layer is subjected to a uniform stray field.

In some embodiments, a width of the synthetic antiferromagnetic layer decreases from the middle of the synthetic antiferromagnetic layer to both ends of the synthetic antiferromagnetic layer, such that the ferromagnetic free layer is subjected to a non-uniform stray field.

In some embodiments, the ferromagnetic free layer is a material with perpendicular magnetic anisotropy.

In some embodiments, the ferromagnetic free layer is a material with tilted magnetic anisotropy.

In some embodiments, the synthetic antiferromagnetic layer includes a ferromagnetic reference layer, a synthetic antiferromagnetic coupling layer, and a bottom ferromagnetic layer; the bottom electrode is arranged on a first side of the bottom ferromagnetic layer, the synthetic antiferromagnetic coupling layer is arranged on a second side of the bottom ferromagnetic layer, and the ferromagnetic reference layer is arranged on a side of the synthetic antiferromagnetic coupling layer away from the bottom ferromagnetic layer, wherein a saturation magnetization of the ferromagnetic reference layer and the bottom ferromagnetic layer is used to determine a compensation degree of the synthetic antiferromagnetic layer, in order to adjust an intensity of the stray field to which the ferromagnetic free layer is subjected.

In some embodiments, an angle between an easy axis of a magnetic moment of the ferromagnetic free layer and a plane in which the ferromagnetic free layer is located is in a range of 30° to 90°.

In some embodiments, the neuron device based on magnetic tunnel junction further includes a heavy metal layer, wherein the heavy metal layer is arranged on the side of the ferromagnetic free layer away from the bottom electrode.

In a second aspect, the present disclosure further provides a neural network apparatus including a neuron device based on magnetic tunnel junction according to any one of the first aspect described above.

In some embodiments, the neural network further includes: a write control word line, a write bit line, a read control word line, a read bit line, a source line, a first switch transistor, and a second switch transistor, wherein the write control word line is connected to a gate of the first switch transistor, the write bit line is connected to the first boundary electrode through the first switch transistor, the read control word line is connected to a gate of the second switch transistor, the read bit line is connected to the top electrode through the second switch transistor, the second boundary electrode is grounded, and the source line is connected to the bottom electrode.

One or more technical solutions provided in the present disclosure have at least the following technical effects or advantages:

1. The neuron device based on magnetic domain wall motion in the present disclosure may simulate the LIF function of neurons under full electronic control and may be used for high-efficiency spiking neuron network (SNN). The stray field to which the ferromagnetic free layer is subjected may be adjusted by the synthetic antiferromagnetic structural layer, the auto-reset function of magnetic domain wall may be achieved, and high reliability self-leakage function may be realized, which is conducive to further miniaturization and integration.

2. The neuron device based on magnetic domain wall motion in the present disclosure may achieve precise adjustment of leakage speed in different regions by simply adjusting the shape of the synthetic antiferromagnetic layer, thereby simulating various linear or nonlinear LIF neuron characteristics with good controllability.

3. The neuron device based on magnetic domain wall motion in the present disclosure makes the magnetic moment of the ferromagnetic free layer have a certain in-plane component by adjusting the thickness of the ferromagnetic free layer with tilted magnetic anisotropy, and increases the movement speed of the magnetic domain wall during integration and leakage at the same time, which may achieve the high-speed neuron device.

4. The neuron device based on magnetic domain wall motion in the present disclosure only needs to reduce the driving current appropriately and adjust the shape of the synthetic antiferromagnetic layer to gradually widen from both ends to the middle, such that the movement speed of the magnetic domain wall first increases and then decreases, and combined with the tunneling magnetoresistance of the magnetic tunnel junction, the Sigmoid activation function in artificial neural morphology networks may be realized, which may be used in common neural network architectures such as Convolutional Neural Network (CNN).

### BRIEF DESCRIPTION OF THE DRAWINGS

FIG. 1 shows a schematic diagram of an implementation structure of a neuron device based on magnetic tunnel junction according to embodiments of the present disclosure.

FIG. 2 shows an image of a position of a magnetic domain wall over time with different orientations of the easy axis of the magnetic moment during neuron leakage according to embodiments of the present disclosure.

FIG. 3 shows an image of a position of a magnetic domain wall over time with different orientations of the easy axis of the magnetic moment during neuron integration according to embodiments of the present disclosure.

FIG. 4 shows an image of a position of a magnetic domain wall over time under the driving of currents of different densities during neuron integration according to embodiments of the present disclosure.

FIG. 5 shows another schematic diagram of an implementation structure of a neuron device based on magnetic tunnel junction according to embodiments of the present disclosure.

FIG. 6 shows an image of a position of a magnetic domain wall over time under different stray field intensities during neuron leakage according to embodiments of the present disclosure.

FIG. 7 shows a spatial distribution image of the stray fields of the synthetic antiferromagnetic layers with different sizes and widths according to embodiments of the present disclosure.

FIG. 8 shows another schematic diagram of an implementation structure of a neuron device based on magnetic tunnel junction according to embodiments of the present disclosure.

FIG. 9 shows another schematic diagram of an implementation structure of a neuron device based on magnetic tunnel junction and a schematic diagram of a magnetic moment easy axis direction according to embodiments of the present disclosure.

FIG. 10 shows a schematic diagram of a structure of a neural network apparatus according to embodiments of the present disclosure.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In addition, in the following descriptions, descriptions of well-known structures and technologies are omitted to avoid unnecessarily obscuring the concept of the present disclosure.

Various schematic structural diagrams according to embodiments of the present disclosure are shown in the accompanying drawings. The drawings are not drawn to scale. Some details are enlarged and some details may be omitted for clarity of presentation. Shapes of various regions and layers as well as relative sizes and positional relationships of the various regions shown in the drawings are only exemplary. In practice, there may be deviations due to manufacturing tolerances or technical limitations, and those skilled in the art may additionally design regions/layers with different shapes, sizes, and relative positions according to actual requirements.

In the context of the present disclosure, when a layer/element is referred to as being “on” another layer/element, the layer/element may be directly on the another layer/element, or there may be an intermediate layer/element between them. In addition, if a layer/element is located “on” another layer/element in one orientation, the layer/element may be located “under” the another layer/element when the orientation is reversed.

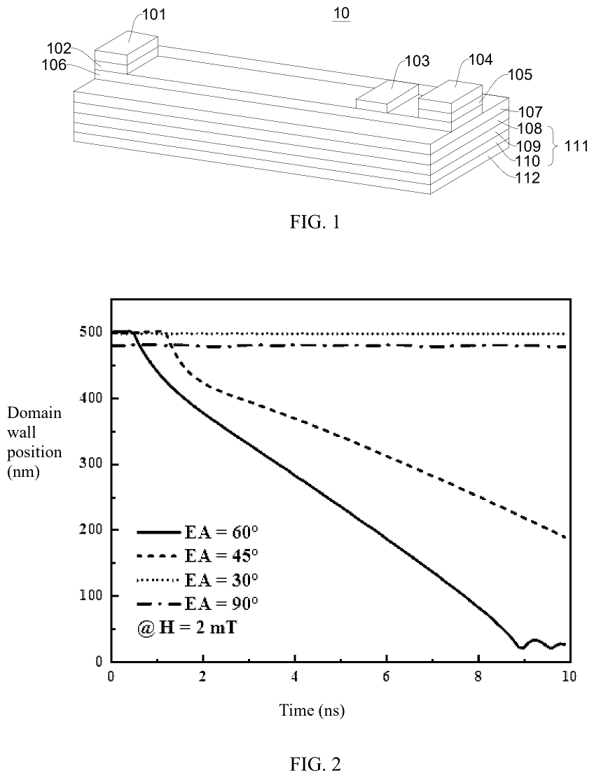

Referring to FIG. 1, in an embodiment of the present disclosure, a neuron device 10 based on magnetic tunnel junction is provided, which may be used to simulate a process of neuron discharge. The neuron device 10 based on magnetic tunnel junction includes: a synthetic antiferromagnetic layer 111, a barrier layer 107, a ferromagnetic free layer 106, a top electrode 103, a first boundary antiferromagnetic structure layer 102, a second boundary antiferromagnetic structure layer 105, a first boundary electrode 101, and a second boundary electrode 104.

A synthetic antiferromagnetic layer 111 (SAF structure) is used to generate a stray field and adjust the stray field to which the ferromagnetic free layer 106 is subjected. A first side of the synthetic antiferromagnetic layer 111 is provided with a bottom electrode.

In some embodiments, the synthetic antiferromagnetic layer 111 includes a ferromagnetic reference layer 108, a synthetic antiferromagnetic coupling layer 109, and a bottom ferromagnetic layer 110. The bottom electrode is arranged on a first side of the bottom ferromagnetic layer 110, the synthetic antiferromagnetic coupling layer 109 is arranged on a second side of the bottom ferromagnetic layer 110, and the ferromagnetic reference layer 108 is arranged on a side of the synthetic antiferromagnetic coupling layer 109 away from the bottom ferromagnetic layer 110. A saturation magnetization of the ferromagnetic reference layer 108 and the bottom ferromagnetic layer 110 is used to determine a compensation degree of the synthetic antiferromagnetic layer 111, in order to generate a stray field with a corresponding intensity. In addition, by adjusting the saturation magnetization of the bottom ferromagnetic layer 110 and the ferromagnetic reference layer 108 in the synthetic antiferromagnetic layer 111, the compensation degree of the synthetic antiferromagnetic layer 111 may be modulated, and the stray fields with different intensities may be generated, so as to achieve the regulation of the overall leakage speed.

In some embodiments, in order to achieve the above-mentioned effect, the composition materials of the bottom ferromagnetic layer 110 and the ferromagnetic reference layer 108 include any one or more of the following materials with perpendicular magnetic anisotropy: CoFeB, CoFe, Co/Pt (multilayer film of alternating cobalt and platinum), Ni/Co (multilayer film of alternating nickel and cobalt). The composition material of the synthetic antiferromagnetic coupling layer 109 includes one or more metals such as Ru and Ta.

The barrier layer 107, i.e. a non-magnetic barrier layer, is arranged on a second side of the synthetic antiferromagnetic layer 111. The composition material of the barrier layer 107 may include any one or more of MgO, HfOx, and Al₂O₃.

The ferromagnetic free layer 106 is arranged on a side of the barrier layer 107 away from the bottom electrode. The composition material of the ferromagnetic free layer 106 may include any one or more of metals such as Co-Ni and Co. In this embodiment, incomplete compensation of the magnetization intensity of the bottom ferromagnetic layer 110 and the ferromagnetic reference layer 108 of the synthetic antiferromagnetic layer 111 may be used to adjust the stray field, so that the magnetic domain wall in the ferromagnetic free layer 106 has a motion trend opposite to the current driving direction, simulating the leakage function of neurons. In this embodiment, the easy axis orientation of the magnetic moment of the ferromagnetic free layer 106 may also be controlled by adjusting a thickness of the ferromagnetic free layer 106, so that the magnetic moment has a certain in-plane component, and the movement speed of the magnetic domain wall during integration and leakage may be improved, thereby achieving the high-speed neuron device. Specifically, an angle between the easy axis of the magnetic moment of the ferromagnetic free layer 106 and the plane in which the ferromagnetic free layer 106 is located (taking the horizontal direction as an example in this embodiment) is in a range of 30° to 90°.

The orientation of the easy axis of the magnetic moment is a result of the competition of various magnetic anisotropies. In some embodiments, when the thickness of the ferromagnetic film is small, due to the effect of surface anisotropy, the orientation of the easy axis of the magnetic moment tends to be in a direction perpendicular to the film. When the deposition incident angle of obliquely depositing films of ferromagnetic material is greater than 60°, the orientation of the easy axis of the magnetic moment will be restricted within the incident plane. Experiments show that when using the oblique deposition method, by adjusting the thickness of the ferromagnetic free layer 106, the orientation of the easy axis of the magnetic moment of the free layer may be adjusted, such that the easy axis of the magnetic moment has a certain in-plane component, which may simultaneously improve the movement speed of the magnetic domain wall during integration and leakage, so as to achieve the high-speed neuron device.

Referring to FIG. 2, FIG. 2 shows an image of a position of a magnetic domain wall over time with different orientations of the easy axis (EA) of the magnetic moment during neuron leakage. A 2 mT stray field is used to achieve neuron leakage, and when the easy axis of the magnetic moment is oriented at an angle of 90° to the in-plane direction, the speed of neuron leakage is very slow, and when the angle between the orientation of the easy axis of the magnetic moment and the in-plane direction decreases to 60°, the magnetic moment has a certain in-plane component, and the speed of neuron leakage increases. When the angle between the orientation of the easy axis of the magnetic moment and the in-plane direction further decreases to 45°, the speed of neuron leakage slows down, but still faster than the case without the in-plane component. When the angle between the orientation of the easy axis of the magnetic moment and the in-plane direction further decreases to 30°, the speed of neuron leakage is similar to the case without the in-plane component. Therefore, by appropriately adjusting the orientation of the easy axis of the free layer to modulate the in-plane component of the magnetic moment, the speed of neuron leakage may be accelerated.

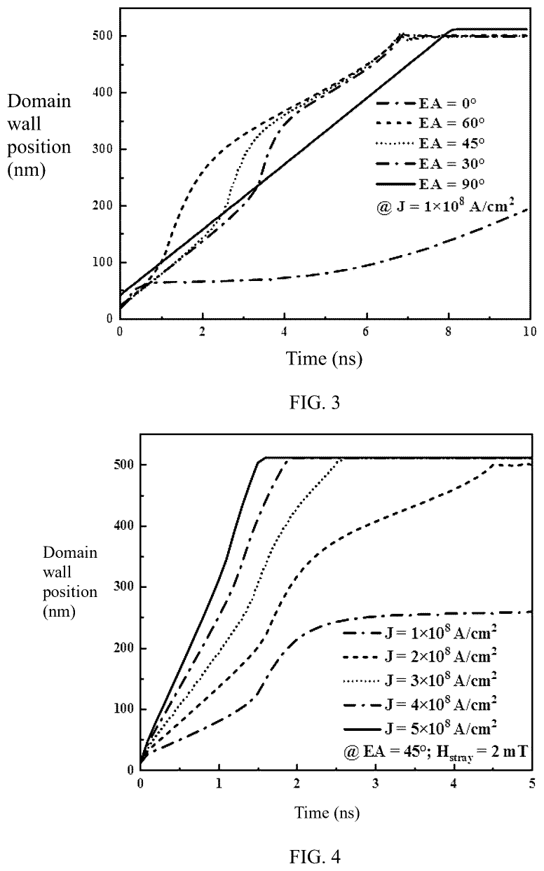

Referring to FIG. 3, FIG. 3 shows an image of a position of a magnetic domain wall over time with different orientations of the easy axis (EA) of the magnetic moment during neuron integration. A current of 1×10⁸ A/cm² is used to drive the movement of the magnetic domain wall, and when the angle between the magnetic moment and the in-plane direction is less than 90° and the magnetic moment has a certain in-plane component, the integration speed of neurons is faster than the case without the in-plane component. As the angle between the orientation of the easy axis of the magnetic moment and the horizontal direction varies between 30°, 45°, and 60°, the overall speed of neuron integration does not change significantly, except for differences in speed at different times during the integration process. When the easy axis of the magnetic moment is oriented at an angle of 0° to the in-plane direction, the spin orbit torque of the driving current has a weak ability to flip the magnetic moment in the in-plane direction, and the integration speed of the magnetic domain wall is the slowest at this point. Therefore, by appropriately adjusting the orientation of the easy axis of the magnetic moment of the ferromagnetic free layer 106, the integration speed of neurons may be accelerated.

In some embodiments, the integration speed of neurons may also be accelerated by adjusting the magnitude of the injected current density, as shown in FIG. 4. FIG. 4 shows an image of a position of a magnetic domain wall over time under the driving of the currents of different densities with the direction of the easy axis of the magnetic moment of the ferromagnetic free layer 106 at 45° and a constant stray field intensity during neuron integration. As the current density increases, the integration speed of the magnetic domain wall accelerates, and the time required to move from the left end to the right end significantly decreases. When the current density is low, the driving action of the spin transfer torque of the spin current on the magnetic domain wall is insufficient to overcome the reverse suppression effect of the stray field, and the magnetic domain wall cannot be driven to the right end. Therefore, in the presence of stray fields, the integration speed of neurons may be adjusted by adjusting the magnitude of the injection current density.

The top electrode 103 is located on a side of the ferromagnetic free layer 106 away from the bottom electrode.

The first boundary antiferromagnetic pinning layer and the second boundary antiferromagnetic pinning layer are both arranged on a side of the ferromagnetic free layer 106 away from the bottom electrode, and are respectively located on two sides of the top electrode 103. The first boundary antiferromagnetic pinning layer and the second boundary antiferromagnetic pinning layer may be made by increasing the thickness of the end portion of the ferromagnetic free layer 106.

The first boundary antiferromagnetic pinning layer and the second boundary antiferromagnetic pinning layer are used to determine a magnetization direction at two ends of the ferromagnetic free layer 106, respectively, so that the magnetic domain wall in the ferromagnetic free layer 106 move between the first boundary antiferromagnetic pinning layer and the second boundary antiferromagnetic pinning layer. Specifically, the magnetization directions of the first boundary antiferromagnetic pinning layer and the second boundary antiferromagnetic pinning layer are opposite to achieve injection and pinning of the magnetic domain wall.

That is, the first boundary antiferromagnetic pinning layer and the second boundary antiferromagnetic pinning layer may pin the magnetic moments at two ends of the ferromagnetic free layer 106 in the +z and −z directions, respectively, as magnetic domain wall nucleation regions. The +z direction is perpendicular to the ferromagnetic free layer 106 and away from the bottom electrode, while the −z direction is opposite to the +z direction. The action of spin transfer torque generated by spin polarized current may drive the magnetic domain wall to move in the ferromagnetic free layer 106, simulating the integration process of neurons. The magnetic moment in the ferromagnetic free layer 106 flips under the action of a stray field generated by the synthetic antiferromagnetic layer 111, so as to achieve the auto-reset function of the magnetic domain wall in the ferromagnetic free layer 106 and simulate the leakage process of neurons. When the motion of magnetic domain wall in the free layer move to the threshold position, the magnetization direction of the ferromagnetic free layer 106 here flips, and the magnetic moment of the ferromagnetic free layer 106 at two ends of the magnetic tunnel junction is switched from an antiparallel state to a parallel state, and the tunneling magnetoresistance is reduced, and combined with external circuits, a current peak signal may be output to simulate the process of neuron discharge.

In some embodiments, the magnetic domain wall in the ferromagnetic free layer 106 is driven to move by the amplitude, pulse width, and number of current pulses from synapses. When there is no current pulse or the current pulse is small, the magnetic domain wall will move in the opposite direction under the action of the SAF structure stray field. When the magnetic domain wall moves to the region where the top electrode 103 is located, that is, the magnetic moment of the ferromagnetic free layer 106 at two ends of the MTJ in the region through which a readout current passes is switched from an antiparallel state to a parallel state, the MTJ is combined with a peripheral circuit to output a current spike signal, thereby simulating the complete leaky-integrate-fire characteristics of the neuron.

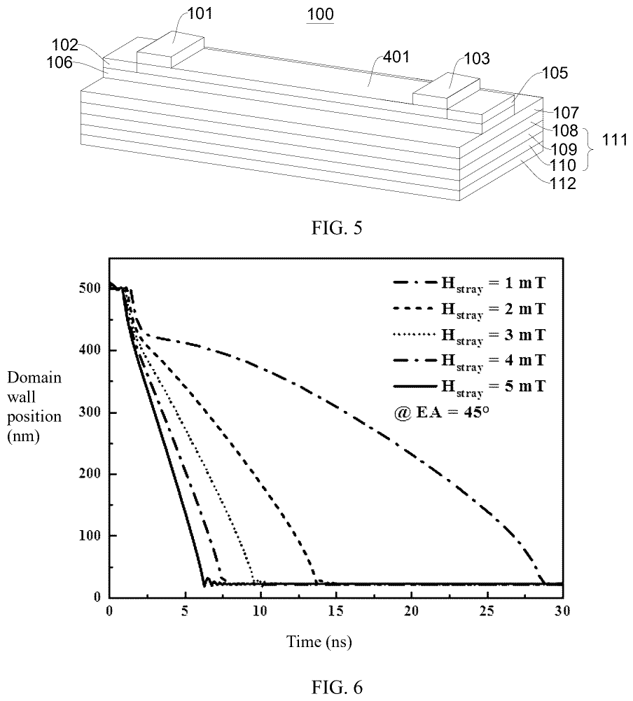

Referring to FIG. 5, in some embodiments, a neuron device 100 of the magnetic tunnel junction may also achieve spin polarized current injection through spin Hall effect by depositing a layer of heavy metal 401 above the ferromagnetic free layer 106, and drive the magnetic domain wall through the spin orbit torque, in addition to generating the spin polarized current at the local pinning region of the boundary of the ferromagnetic free layer 106, and driving the magnetic domain wall through the spin transfer torque.

In some embodiments, the materials of the top electrode 103, the first boundary electrode 101, and the second boundary electrode 104 may include one or more metals such as Cu and Au.

The first boundary electrode 101 is arranged on a side of the first boundary antiferromagnetic pinning layer away from the bottom electrode; and the second boundary electrode 104 is arranged on a side of the second boundary antiferromagnetic pinning layer away from the bottom electrode.

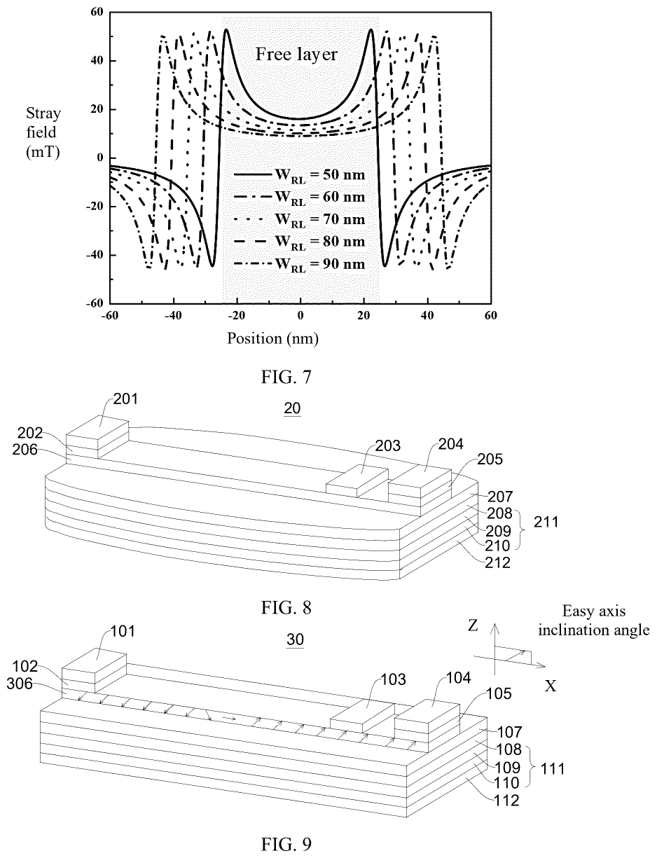

In some embodiments, the widths of the synthetic antiferromagnetic layer 111 at different length positions may be designed to regulate the stray field intensities of the ferromagnetic free layer 106 in different regions, thereby controlling the leakage speed in different regions and achieving various linear/nonlinear neuron characteristics. Referring to FIG. 6, FIG. 6 shows an image of a position of a magnetic domain wall over time under different stray field intensities with the easy axis direction of the magnetic moment of the ferromagnetic free layer 106 at 45° during neuron leakage. When no current is injected, as the stray field intensity increases, the speed of magnetic domain wall leakage accelerates, and the time required to return from the right end to the left end is significantly reduced. Therefore, the leakage process of neurons may be effectively realized by utilizing the stray field, and the leakage speed of neurons may be adjusted by adjusting the intensity of the stray field. Referring to FIG. 7, FIG. 7 shows a spatial distribution image of the stray fields of SAF structures with different sizes and widths. The smaller the size and width of the SAF structure, the closer the distance between the ferromagnetic free layer 106 and the edge of the SAF structure, and the greater the stray field effect on the ferromagnetic free layer 106. Therefore, the magnitude of the stray field to which the ferromagnetic free layer 106 is subjected may be effectively controlled by adjusting the size and width of the SAF structure.

For example, in some embodiments, the width of different length positions of the synthetic antiferromagnetic layer 111 may be set to be the same, so as to ensure that the synthetic antiferromagnetic layer 111 generates a uniform stray field, such that the ferromagnetic free layer 106 is subjected to a uniform stray field, and linear neuron characteristics are achieved, as shown in FIG. 1.

For another example, in some embodiments, referring to FIG. 8, a neuron device 20 of the magnetic tunnel junction includes: a synthetic antiferromagnetic layer 211, a barrier layer 207, a ferromagnetic free layer 206, a top electrode 203, a first boundary antiferromagnetic structure layer 202, a second boundary antiferromagnetic layer 205, a first boundary electrode 201, and a second boundary electrode 204. The synthetic antiferromagnetic layer 211 includes a ferromagnetic reference layer 208, a synthetic antiferromagnetic coupling layer 209, and a bottom ferromagnetic layer 110. The width of the synthetic antiferromagnetic layer 211 may be set to decrease from the middle of the synthetic antiferromagnetic layer 211 to two ends of the synthetic antiferromagnetic layer 211, thereby ensuring that the synthetic antiferromagnetic layer 211 generates a non-uniform stray field, such that the ferromagnetic free layer 206 is subjected to a non-uniform stray field, and nonlinear neuronal characteristics are achieved. Specifically, the shape of the synthetic antiferromagnetic layer 211 may be set to gradually widen from two ends towards the middle, so that the reverse suppression effect of the stray field to which the ferromagnetic free layer 206 is subjected during movement gradually weakens from two ends towards the middle. The movement speed of the magnetic domain wall first increases and then decreases, and the resistance of the magnetic tunnel junction is linearly related to the movement distance of the magnetic domain wall in the ferromagnetic free layer 206. This may achieve a nonlinear Sigmoid function relationship between the number of pulses and the tunneling current of the magnetic tunnel junction.

The principles of the present disclosure will be further illustrated and described below with reference to practical examples and illustrations.

Continuing to refer to FIG. 1, in the neuron device 10 based on magnetic tunnel junction shown in FIG. 1, the first antiferromagnetic pinning layer on the left side pins the magnetization direction of the left end region of the ferromagnetic free layer 106 in the −z direction, and the second antiferromagnetic pinning layer on the right side pins the magnetization direction of the right end region of the ferromagnetic free layer 106 in the +z direction. The magnetic domain wall in the ferromagnetic free layer 106 moves between the pinned regions on two ends without annihilation. The magnetization direction of the bottom ferromagnetic layer 110 is in the +z direction, and the magnetization direction of the ferromagnetic reference layer 108 is in the −z direction. The saturation magnetization of the bottom ferromagnetic layer 110 is greater than the saturation magnetization of the ferromagnetic reference layer 108, and the magnetic fields generated by the two are not fully compensated. The synthetic antiferromagnetic coupling layer 109, and the bottom ferromagnetic layer 110 and the ferromagnetic reference layer 108 on both sides form an SAF structure. The SAF structure may adjust the generated stray field to make the magnetization direction of the ferromagnetic free layer 106 above the SAF structure tend towards the +z direction, that is, to make the magnetic domain wall move in the −x direction (in the length direction of the ferromagnetic free layer 106 and towards the direction where the first boundary electrode 101 is located), so as to simulate the leakage process of neurons. When the width of the SAF structure is the same (i.e. the structure shown in FIG. 1), the ferromagnetic free layer 106 may be subjected to a uniform stray field, achieving linear reverse driving of the magnetic domain walls of the ferromagnetic free layer 106, thereby achieving a uniform leakage speed.

When the width of the SAF layer varies at different length positions, as shown in FIG. 8, the ferromagnetic free layer 206 may be subjected to a non-uniform stray field to achieve the nonlinear reverse driving of the magnetic domain wall of the ferromagnetic free layer 206, thereby achieving non-uniform leakage speed. In an initial state, the magnetization direction of the non-magnetic domain pinning region in the ferromagnetic free layer 206 is in the +z direction, that is, the magnetic domain wall is located at the boundary of the left-end pinned region. When there is current excitation, the magnetization direction of the ferromagnetic free layer 206 flips towards the −z direction through the spin transfer torque effect of spin polarized current, i.e., driving the magnetic domain wall to move in the +x direction (the opposite direction of the −x direction), and the integration process of neurons is simulated. After a series of integration and leakage processes, when the magnetic domain wall moves to a corresponding region below the top electrode 203, the magnetization direction of the ferromagnetic free layer 206 and ferromagnetic reference layer 208 at two ends of the MTJ in the region through which a readout current between the top and bottom electrodes passes is switched from antiparallel to parallel, and the tunneling resistance is reduced, and combined with the peripheral circuit, a current peak signal is output to simulate the discharge process of neurons.

Continuing to refer to FIG. 8, FIG. 8 shows a neuron device based on magnetic tunnel junction implementing nonlinear Sigmoid function with non-uniform stray field. The shape and width of the SAF structure in this example are non-uniform, where the width of the SAF structure gradually widens from both ends towards the middle. When the current pulse is small, the spin transfer torque drives the magnetic domain wall in the ferromagnetic free layer 206 to move in the +x direction, and the stray field generated by the SAF structure causes the magnetic domain wall in the ferromagnetic free layer 206 to move along the −x direction, and the two compete with each other. Since the larger the distance between the ferromagnetic free layer 206 and the edge of the synthetic antiferromagnetic layer 211 is, the smaller the stray field effect on the ferromagnetic free layer 206 is, the reverse suppression effect of the stray field on the magnetic domain wall during motion gradually weakens from both ends to the middle, and the motion speed of the magnetic domain wall first increases and then decreases. Due to the linear correlation between the tunneling magnetoresistance of the magnetic tunnel junction and the movement distance of the magnetic domain wall in the ferromagnetic free layer 206, a nonlinear Sigmoid function relationship between the number of current pulses and the tunneling current of the magnetic tunnel junction may be achieved.

Referring to FIG. 9, FIG. 9 shows a schematic diagram of easy axis direction of the magnetic moment when the neuron device 30 based on magnetic tunnel junction is a high-speed neuron device achieved by utilizing the in-plane component. The difference from the example corresponding to FIG. 1 is that the easy axis direction of the magnetic moment of the ferromagnetic free layer 306 is different. The ferromagnetic free layer 106 in FIG. 1 has perpendicular magnetic anisotropy, while the ferromagnetic free layer 306 in FIG. 3 has oblique magnetic anisotropy with a magnetic moment easy axis oriented at a certain angle to the y-axis, the magnetic moment easy axis having a certain in-plane component. By utilizing the in-plane component of magnetic moment, the switching efficiency of magnetic moment may be improved, and the movement speed of the magnetic domain wall may be improved simultaneously during integration and leakage, thereby achieving the high-speed neuron device.

It should also be noted that:

1. The size of each layer dimensional structure of the neuron device 10 based on magnetic tunnel junction provided in this embodiment may be miniaturized according to the process.

2. The shapes of the synthetic antiferromagnetic layer 111 and ferromagnetic free layer 106 used to adjust the intensity of the stray field may be replaced with various linear or nonlinear geometric shapes, such as squares, rectangular diamonds, ellipses, circles, or other irregular shapes in the xy plane, etc., to simulate various linear or nonlinear characteristics of neurons.

3. The in-plane component of the magnetic moment in the ferromagnetic free layer 106 may also be adjusted by annealing under a certain magnetic field.

In summary, the neuron device 10 based on magnetic tunnel junction provided in the present disclosure has at least the following beneficial effects.

1. The neuron device based on magnetic domain wall motion in the present disclosure may simulate the LIF function of neurons under full electronic control and may be used for high-efficiency spiking neuron network (SNN). The stray field to which the ferromagnetic free layer is subjected may be adjusted by the SAF structure, the automatic retraction of magnetic domain wall may be achieved, and high reliability self-leakage function may be realized, which is conducive to further miniaturization and integration.

2. The neuron device based on magnetic domain wall motion in the present disclosure may achieve precise adjustment of leakage speed in different regions by simply adjusting the shape of the SAF structure, thereby simulating various linear or nonlinear LIF neuron characteristics with good controllability.

3. The neuron device based on magnetic domain wall motion in the present disclosure makes the magnetic moment of the ferromagnetic free layer 106 have a certain in-plane component by adjusting the thickness of the ferromagnetic free layer 106 with tilted magnetic anisotropy, and increases the movement speed of the magnetic domain wall during accumulation and leakage at the same time, which may achieve the high-speed neuron device.

4. The neuron device based on magnetic domain wall motion in the present disclosure only needs to reduce the driving current appropriately and adjust the shape of the SAF structure to gradually widen from both ends to the middle, such that the movement speed of the magnetic domain wall first increases and then decreases, and combined with the tunneling magneto resistance relationship of the magnetic tunnel junction, the Sigmoid activation function in artificial neural morphology networks may be realized, which may be used in common neural network architectures such as Convolutional Neural Network (CNN).

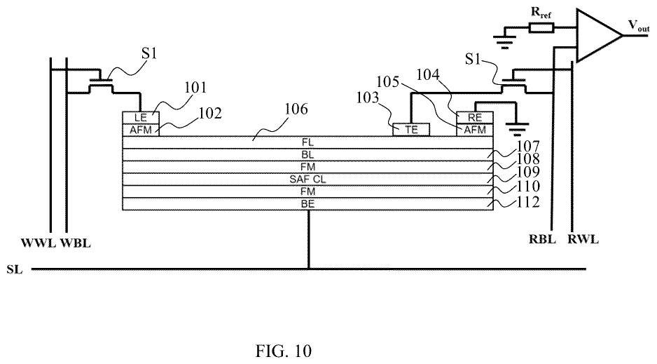

In another aspect of the present disclosure, there is further provided a neural network apparatus, including a neuron device based on magnetic tunnel junction according to any one of the aforementioned embodiments. Specifically, referring to FIG. 10, FIG. 10 shows a schematic diagram of a read-write unit structure of a neural network apparatus. The read-write unit structure circuit adopts an MTJ structure, including a write control word line WWL, a write bit line WBL, a read control word line RWL, a read bit line RBL, a source line SL, a first switch transistor S1 and a second switch transistor S2. The write control word line WWL is connected a gate of the first switch transistor S1 for controlling the on and off of the first switch transistor S1. The write bit line WBL is connected to the first boundary electrode 101 through the first switch transistor S1, the read control word line RWL is connected to a gate of the second switch transistor S2 for controlling the on and off of the second switch transistor S2, the read bit line RBL is connected to the top electrode 103 through the second switch transistor S2, the second boundary electrode 104 is grounded, and the source line SL is connected to the bottom electrode.

When the write control word line WWL is turned on, a current path is formed through the write bit line WBL-magnetic domain wall transport free layer-ground. The injected current is controlled by the electrical signal on the write bit line WBL to drive the magnetic domain wall to move. When the read control word line RWL is turned on, a current path is formed through the read bit line RBL-magnetic tunnel junction (MTJ)-source line SL-ground, allowing for the reading of electrical signals released by the neuron device. When the magnetic domain wall moves to a corresponding region below the top electrode 103, the tunneling magnetoresistance of MTJ decreases. A current spike signal may be output through the read bit line RBL, and the signal may also be output after being amplified by a signal of a comparison amplifier.

It should be noted that the neural network apparatus provided in the present disclosure adopts the neuron device based on magnetic tunnel junction in the aforementioned embodiments as a basic component unit. Therefore, the neural network apparatus also has the same beneficial effects as the neuron device based on magnetic tunnel junction in the aforementioned embodiments, which may be specifically referred to the aforementioned embodiments and will not be described in details in this embodiment.

In the above description, the technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

While the preferred embodiments of the present disclosure have been described, additional variations and modifications in those embodiments may occur to those skilled in the art once they learn of the basic inventive concepts. Therefore, the appended claims are intended to be interpreted as including preferred embodiments and all variations and modifications falling within the scope of the present disclosure.

Obviously, those skilled in the art may make various modifications and variations to the present disclosure without departing from the spirit and scope of the present disclosure. In this way, if these modifications and variations of the present disclosure fall within the scope of the claims and their equivalents, then the present disclosure is also intended to include these modifications and variations.

1. A neuron device based on magnetic tunnel junction, comprising:
a synthetic antiferromagnetic layer, wherein a first side of the synthetic antiferromagnetic layer is provided with a bottom electrode;
a barrier layer arranged on a second side of the synthetic antiferromagnetic layer;
a ferromagnetic free layer arranged on a side of the barrier layer away from the bottom electrode, wherein a stray field to which the ferromagnetic free layer is subjected is determined by a structure of the synthetic antiferromagnetic layer;
a top electrode arranged on a side of the ferromagnetic free layer away from the bottom electrode;
a first boundary antiferromagnetic pinning layer and a second boundary antiferromagnetic pinning layer both arranged on the side of the ferromagnetic free layer away from the bottom electrode, and respectively located on two sides of the top electrode, wherein the first boundary antiferromagnetic pinning layer and the second boundary antiferromagnetic pinning layer are respectively used to determine a magnetization direction at two ends of the ferromagnetic free layer, such that a magnetic domain wall in the ferromagnetic free layer move between the first boundary antiferromagnetic pinning layer and the second boundary antiferromagnetic pinning layer;
a first boundary electrode arranged on a side of the first boundary antiferromagnetic pinning layer away from the bottom electrode; and a second boundary electrode arranged on a side of the second boundary antiferromagnetic pinning layer away from the bottom electrode.

2. The neuron device based on magnetic tunnel junction according to claim 1, wherein a width of the synthetic antiferromagnetic layer at different length positions is the same, such that the ferromagnetic free layer is subjected to a uniform stray field.

3. The neuron device based on magnetic tunnel junction according to claim 1, wherein a width of the synthetic antiferromagnetic layer decreases from the middle of the synthetic antiferromagnetic layer to both ends of the synthetic antiferromagnetic layer, such that the ferromagnetic free layer is subjected to a non-uniform stray field.

4. The neuron device based on magnetic tunnel junction according to claim 1, wherein the ferromagnetic free layer is a material with perpendicular magnetic anisotropy.

5. The neuron device based on magnetic tunnel junction according to claim 1, wherein the ferromagnetic free layer is a material with tilted magnetic anisotropy.

6. The neuron device based on magnetic tunnel junction according to claim 1, wherein the synthetic antiferromagnetic layer comprises a ferromagnetic reference layer, a synthetic antiferromagnetic coupling layer, and a bottom ferromagnetic layer; the bottom electrode is arranged on a first side of the bottom ferromagnetic layer, the synthetic antiferromagnetic coupling layer is arranged on a second side of the bottom ferromagnetic layer, and the ferromagnetic reference layer is arranged on a side of the synthetic antiferromagnetic coupling layer away from the bottom ferromagnetic layer;
wherein a saturation magnetization of the ferromagnetic reference layer and the bottom ferromagnetic layer is used to determine a compensation degree of the synthetic antiferromagnetic layer, in order to adjust an intensity of the stray field to which the ferromagnetic free layer is subjected.

7. The neuron device based on magnetic tunnel junction according to claim 1, wherein an angle between an easy axis of a magnetic moment of the ferromagnetic free layer and a plane in which the ferromagnetic free layer is located is in a range of 30° to 90°.

8. The neuron device based on magnetic tunnel junction according to claim 1, further comprising a heavy metal layer, wherein the heavy metal layer is arranged on the side of the ferromagnetic free layer away from the bottom electrode.

9. A neural network apparatus comprising a neuron device based on magnetic tunnel junction according to claim 1.

10. The neural network apparatus according to claim 9, further comprising: a write control word line, a write bit line, a read control word line, a read bit line, a source line, a first switch transistor, and a second switch transistor, wherein the write control word line is connected to a gate of the first switch transistor, the write bit line is connected to the first boundary electrode through the first switch transistor, the read control word line is connected to a gate of the second switch transistor, the read bit line is connected to the top electrode through the second switch transistor, the second boundary electrode is grounded, and the source line is connected to the bottom electrode.
